(19) United States
(12) Patent Application Publication
(10) Pub. No.: US 2017/0098476 A1
(43) Pub. Date: Apr. 6, 2017

(54) COMPRESSION CIRCUIT, TEST APPARATUS, AND SEMICONDUCTOR MEMORY APPARATUS AND SEMICONDUCTOR APPARATUS HAVING THE SAME

(71) Applicant: SK hynix Inc., Icheon-si Gyeonggi-do (KR)

(72) Inventor: Yun Gi HONG, Icheon-si Gyeonggi-do (KR)

(21) Appl. No.: 14/983,132

(22) Filed: Dec. 29, 2015

(30) Foreign Application Priority Data
Oct. 1, 2015 (KR) 10-2015-0138508

(51) Int. Cl. G11C 29/12; G11C 7/22; G06F 3/06

(52) U.S. Cl. CPC G11C 29/1201; G06F 3/0604; G06F 3/0656; G06F 3/0673; G11C 7/22; G06F 3/0638

(57) ABSTRACT

A semiconductor memory apparatus includes a first data compressor configured to generate at least one compression signal based on test data provided in a memory circuit, and a second data compressor configured to generate grouping data by grouping the at least one compression signal in preset bit units and generate an output signal having a voltage level corresponding to a logic level of the grouping data.

### CROSS-REFERENCES TO RELATED APPLICATION

This application claims priority under 35 U.S.C. 119(a) to Korean application No. 10-2015-0138508, filed on Oct. 1, 2015, in the Korean intellectual property Office, which is incorporated by reference in its entirety as set forth in full.

### BACKGROUND

1. Technical Field

Various embodiments generally relate to a circuit, test apparatus, and semiconductor integrated circuit device, and more particularly, to a compression circuit, test apparatus, and semiconductor apparatus and a semiconductor apparatus having the same.

2. Related Art

After fabrication of semiconductor memory apparatuses the semiconductor memory apparatuses are tested for failures.

Semiconductor memory apparatuses are continuously being developed to provide higher integration and higher capacities, and thus, inevitably, a lot of test time for the semiconductor memory apparatuses is required.

The compression test method may be used to reduce the time and cost required for the tests.

The semiconductor memory region is divided into at least two or more sub regions for the compression test. The test data having the same level may be simultaneously stored in cells in each of the divided sub regions and may be simultaneously output from the cells in the sub region. The test data output from each sub region may be generated as a comparison signal which is compressed in a single signal, and an operation of determining whether or not the cell is failed according to the level of the comparison signal may be performed.

The test efficiency of the semiconductor memory apparatus may depend on the number of input/output (I/O) channels provided in the semiconductor memory apparatus or the number of I/O channels provided in the test apparatus. This is because the number of I/O channels which can simultaneously output compressed test data are limited even when the compression test method is used.

Accordingly, there is a need for a method for overcoming the physical environments of the semiconductor memory apparatus or the test apparatus and efficiently performing the test.

### BRIEF DESCRIPTION OF THE DRAWINGS

FIG. 1 is a configuration diagram illustrating a representation of an example of a semiconductor memory apparatus according to an embodiment.

FIG. 2 is a configuration diagram illustrating a representation of an example of a second data compressor according to an embodiment.

FIG. 3 is a configuration diagram illustrating a representation of an example of an encoder according to an embodiment.

FIG. 4 is a diagram explaining a representation of an example of a grouping concept according to an embodiment.

FIG. 5 is a configuration diagram illustrating a representation of an example of an encoder according to an embodiment.

FIG. 6 is a diagram explaining a representation of an example of a grouping concept according to an embodiment.

FIG. 7 is a configuration diagram illustrating a representation of an example of an output circuit according to an embodiment.

FIG. 8 is a configuration diagram illustrating a representation of an example of a semiconductor apparatus according to an embodiment.

FIG. 9 is a configuration diagram illustrating a representation of an example of a detector according to an embodiment.

### DETAILED DESCRIPTION

According to an embodiment, there is provided a semiconductor memory apparatus. The semiconductor memory apparatus may include a first data compressor configured to generate at least one compression signal based on test data provided in a memory circuit. The semiconductor memory apparatus may include a second data compressor configured to generate grouping data by grouping the at least one compression signal in preset bit units and may generate an output signal having a voltage level corresponding to a logic level of the grouping data.

According to an embodiment, there is provided a semiconductor memory apparatus. The semiconductor memory apparatus may include a first data compressor configured to generate at least one parallel compression signal simultaneously output by receiving test data from a memory circuit. The semiconductor memory apparatus may include a parallel to serial converter configured to convert the parallel compression signal to a serial compression signal. The semiconductor memory apparatus may include an encoder configured to generate grouping data by grouping the serial compression signal in preset bit units. The semiconductor memory apparatus may include an output circuit configured to generate an output signal having a voltage level corresponding to a logic level of the grouping data.

According to an embodiment, there is provided a semiconductor apparatus. The semiconductor apparatus may include a semiconductor memory apparatus configured to generate grouping data by grouping at least one compression signal generated in response to test data provided from a memory circuit in preset bit units and may generate an output signal having a voltage level corresponding to a logic level of the grouping data. The semiconductor apparatus may include a test apparatus configured to determine whether the semiconductor memory apparatus is PASS or FAIL in response to the output signal.

According to an embodiment, there is provided a compression circuit. The compression circuit may include a first data compressor configured to generate at least one compression signal based on test data. The compression circuit may include a second data compressor configured to generate grouping data by grouping the at least one compression signal in preset bit units and may generate an output signal having a voltage level corresponding to a logic level of the grouping data.

According to an embodiment, there is provided a compression circuit. The compression circuit may include a first data compressor configured to generate at least one parallel compression signal simultaneously output by receiving test data. The compression circuit may include a parallel to serial converter configured to convert the parallel compression signal to a serial compression signal. The compression circuit may include an encoder configured to generate grouping data by grouping the serial compression signal in preset bit units. The compression circuit may include an output circuit configured to generate an output signal having a voltage level corresponding to a logic level of the grouping data.

According to an embodiment, there is provided a test apparatus. The test apparatus may include a detector configured to receive an output signal having a voltage level corresponding to a logic level of grouping data to determine whether a memory region has failed. The grouping data may be generated by grouping at least one compression signal generated in response to test data provided in preset bit units

Various examples of embodiments will be described with reference to the accompanying drawings. Various examples of embodiments are described herein with reference to cross-sectional illustrations that are schematic illustrations of examples of embodiments (and intermediate structures). As such, variations from the shapes of the illustrations as a result, for example, of manufacturing techniques and/or tolerances, are to be expected. Thus, embodiments should not be construed as limited to the particular shapes illustrated herein but may include deviations in shapes that result, for example, from manufacturing. In the drawings, lengths and sizes of layers and regions may be exaggerated for clarity. Like reference numerals in the drawings denote like elements. It is also to be understood that when a layer is referred to as being “on” another layer or substrate, it can be directly on the other or substrate, or intervening layers may also be present. It is also noted that in this specification, “connected/coupled” refers to one component not only directly coupling another component but also indirectly coupling another component through an intermediate component. In addition, a singular form may include a plural form, and vice versa as long as it is not specifically mentioned.

The concepts are described herein with reference to cross-section and/or plan illustrations of embodiments. However, the embodiments herein should not be construed as limiting the concepts. Although a few embodiments will be illustrated and described, it will be appreciated by those of ordinary skill in the art that changes may be made in these examples of the embodiments without departing from the principles and spirit of the disclosure.

FIG. 1 is a configuration diagram illustrating a representation of an example of a semiconductor memory apparatus according to an embodiment.

Referring to FIG. 1, a semiconductor memory apparatus 10 according to an embodiment may include a first data compressor 100 and a second data compressor 200.

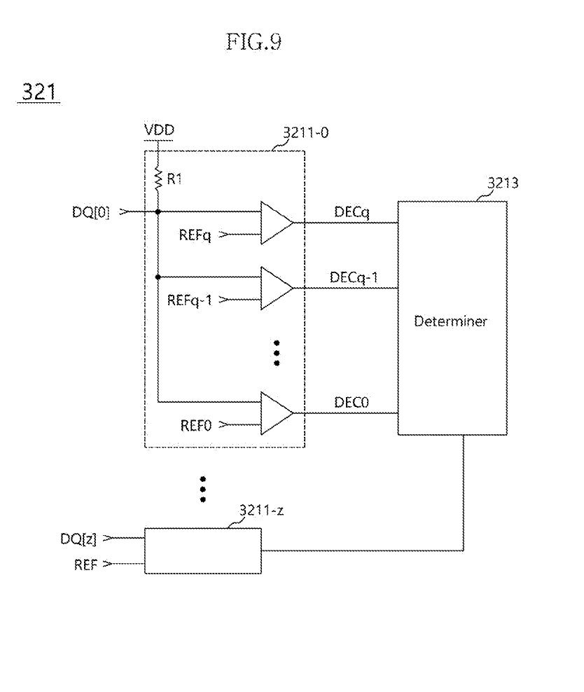

The first data compressor 100 may generate compression signals COMP_PD0<0:n> to COMP_PDm<0:n>, which are simultaneously output, by compressing test data TEST_RD<0:y> read out from a memory circuit (see 311 of FIG. 8) in a preset compression rate.

In an embodiment, the first data compressor 100 may compress the test data TEST_RD<0:y> transmitted from the memory circuit through a plurality of data transmission lines (for example, global I/O lines (GIO)) and output the compression signal. The compression rate of the first data compressor 100 may be information which determines whether or not to receive and compress how many data of data transmission lines. The phrase “compress data” may refer to “generate a result indicating whether logic levels of pieces of data input to the first data compressor 100 are the same or the logic level of any one among the pieces of data is different from logic levels of the remaining data, according to the preset compression rate”.

The first data compressor 100 may include a plurality of compression circuits therein. Each compression circuit may be configured to receive the test data TEST_RD<0:y> from the preset number of data transmission lines and compress the received test data TEST_RD<0:y>.

As described above, compression signals COMP_PD0<0:n> to COMP_PDm<0:n> may be simultaneously output from the first data compressor 100. That is, the compression signals COMP_PD0<0:n> to COMP_PDm<0:n> may be output through the data transmission lines Line_0 to Line_m in parallel.

The second data compressor 200 may receive the compression signals COMP_PD0<0:n> to COMP_PDm<0:n> transmitted through at least one data transmission line Line_0 to Line_m, and generate grouping data by grouping bit signals in each of the compression signals COMP_PD0<0:n> to COMP_PDm<0:n> in preset bit units. The second data compressor 200 may generate an output signal DQ<0:z> having a voltage level corresponding to a logic level of the grouping data.

In an embodiment, the second data compressor 200 may encode the compression signals COMP_PD0<0:n> to COMP_PDm<0:n>, which are transmitted in parallel by (n+1) bits through the data transmission lines Line_0 to Line_m, in such a manner that bit signals of the compression signal in each data transmission line Line_0 to Line_m are grouped in units of a preset number (/+1). For example, ((n+1)/(/+1)) pieces of grouping data may be generated by grouping the (n+1) bit signals of the compression signal COMP_PD0<0:n> transmitted through the first data transmission line Line_0 by the preset number (/+1), and the data grouping may be performed on the compression signals transmitted through the data transmission lines Line_0 to Line_m. The ((n+1)/(/+1)) pieces of grouping data may be generated in each of the data transmission lines Line_0 to Line_m.

In an embodiment, the second data compressor 200 may encode the compression signals COMP_PD0<0:n> to COMP_PDm<0:n>, which are transmitted in parallel by (n+1) bits through the data transmission lines Line_0 to Line_m, in such a manner that bit signals of the compression signals transmitted through the data transmission lines Line_0 to Line_m, that is, the bit signals of the compression signals in the same bit position among the bit positions of each of the compression signals are grouped in units of preset number (/+1). For example, ((m+1)/(/+1)) pieces of grouping data may be generated by grouping the first bit signals of the compression signals COMP_PD0[0] to COMP_PDm[0] in the data transmission lines Line_0 to Line_m in units of preset number (/+1), and the data grouping may be performed on the bit signals in each of the bit positions <0:n> of the compression signals. The ((m+1)/(/+1)) pieces of grouping data may be generated with respect to each of the bit positions <0:n>.

When the grouping data is generated through the grouping method, the second data compressor 200 may output the output signal DQ<0:z> having a voltage level corresponding a logic level of the grouping data through a corresponding output channel.

When the second data compressor 200 compresses the compression signals COMP_PD0<0:n> to COMP_PDm<0:n> in the data transmission lines Line_0 to Line_m in bit units of the preset number (/+1), the output signal DQ<0:z> may be output through m output channels (z=m). When the compression signals COMP_PD0<0:n> to COMP_PDm<0:m> are not grouped, data may be output through output channels in a (n+1) burst length. However, when the data is grouped in (/+1) bit units through the second data compressor 200 as in the embodiment, data may be output in a burst length (n+1)/(/+1). Accordingly, the final output point of time when the test data is output through each output channel may be advanced.

When the second data compressor 200 compresses bit signals in each bit position of the compression signals COMP_PD0<0:n> to COMP_PDm<0:n> in the data transmission lines Line_0 to Line_m in units of the preset number (/+1), the output signal DQ<0:z> may be output through ((m+1)/(/+1)) output channels (z=(m+1)/(/+1)). The compression signals COMP_PD0<0:n> to COMP_PDm<0:n> are not grouped, m output channels may be necessary. However, when the grouping data is generated in units of (/+1) bit signals as in the embodiment, only ((m+1)/(/+1)) output channels may be necessary. Accordingly, other test data may be simultaneously output through spare output channels, and thus the test speed may be remarkably improved.

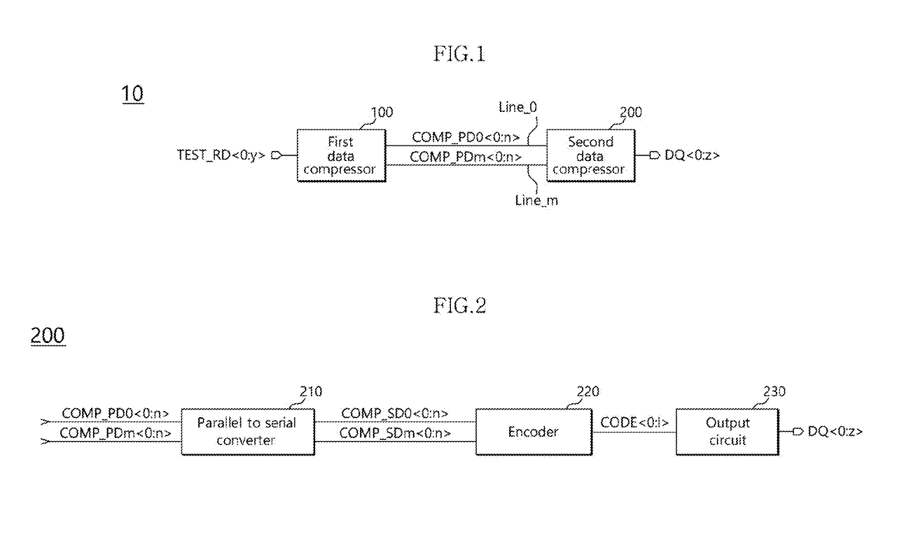

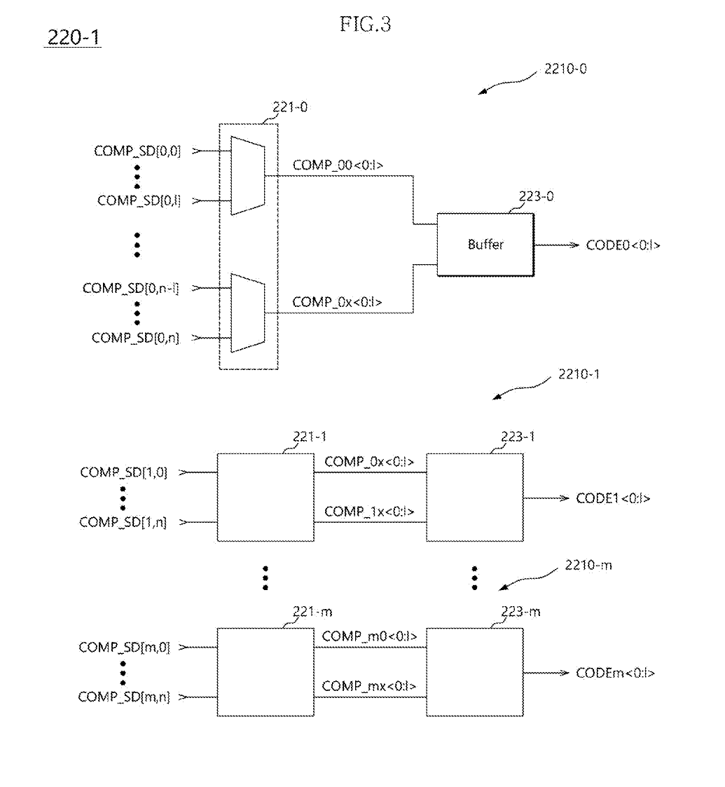

FIG. 2 is a configuration diagram illustrating a representation of an example of a second data compressor according to an embodiment.

The second data compressor 200 according to an embodiment may include a parallel to serial converter 210, an encoder 220, and an output circuit 230.

The parallel to serial converter 210 may be configured to generate serial compression signals COMP_SD®<0:n> to COMP_SDm<0:n> by performing serialization on the compression signals COMP_PD0<0:n> to COMP_PDm<0:n> which are simultaneously provided in parallel through at least one data transmission line Line_0 to Line_m. In an embodiment, the parallel to serial converter 210 may be configured to include a pipe latch, but the configuration of the parallel to serial converter 210 is not limited thereto.

The encoder 220 may generate the grouping data by grouping the serial compression signals COMP_SD0<0:n> to COMP_SDm<0:n> in preset number units through a preset method. The encoder 220 may be configured to output the grouping data as a compression signal CODE<0:/>.

As the method of grouping the serial compression signals COMP_SD0<0:n> to COMP_SDm<0:n> through the encoder 220, one of the method (Case \textcircled{1}) of encoding the bit signals of each of the serial compression signals COMP_SD0<0:n> to COMP_SDm<0:n> in the data transmission lines Line_0 to Line_m and the method (Case \textcircled{2}) of encoding the bit signals of the serial compression signals COMP_SD0<0:n> to COMP_SDm<0:n> located in the same bit position in the data transmission lines Line_0 to Line_m may be selected, but the encoding method is not limited thereto.

The unit (/+1) for grouping the serial compression signals COMP_SD0<0:n> to COMP_SDm<0:n> through the encoder 220 may be preset, and the unit (/+1) may be defined as (/+1)=2^{a}≦(n or m)+1 (a is natural number, n=Case \textcircled{1}, and m=Case \textcircled{2}).

The grouping data, which is generated by grouping the serial compression signals COMP_SD0<0:n> to COMP_SDm<0:n> in preset number units through the preset method in the encoder 220, may be output as a compression signal CODE<0:/>. The output circuit 230 may output the output signal DQ<0:z> corresponding to a logic level of the compression signal CODE<0:/> through a corresponding output channel.

[Case \textcircled{1}] In an embodiment, the encoder 220 may compress the bit signals of each of the serial compression signals COMP_SD0<0:n> to COMP_SDm<0:n> in the data transmission lines Line_0 to Line_m in units of preset number (/+1). In the embodiment, (n+1) pieces of data (that is, (n+1) pieces of bit data of each compression signal) transmitted through each of the data transmission lines Line_0 to Line_m may be grouped, that is, secondarily compressed to ((n+1)/(/+1)) pieces of data. The ((n+1)/(/+1)) pieces of grouping data may be generated in each of the data transmission lines Line_0 to Line_m. The grouping data generated in each of the data transmission lines Line_0 to Line_m may be output as the compression signal CODE<0:/>, and the output circuit 230 may output the output signal DQ<0:z> corresponding to the logic level of the compression signal CODE<0:/> through m output channels. The burst length of the signal output through each of the output channels may be (n+1)/(/+1). The output signals DQ<0:z> based on the compression signals CODE<0:/> generated in the same data transmission line Line_0 to Line_m may be sequentially output through a corresponding output channel. The output signals DQ<0:z> based on the compression signals CODE<0:/> generated in different data transmission lines Line_0 to Line_m may be simultaneously output through corresponding output channels, that is, may be output through the output channels in parallel.

[Case \textcircled{2}] In an embodiment, the encoder 220 may compress the bit signals in each of the bit positions of the serial compression signals COMP_SD0<0:n> to COMP_SDm<0:n> in the data transmission lines Lines Line_0 to Line_m in units of preset number (/+1). In the embodiment, the data of each bit position (that is, m pieces of bit data of the serial compression signals in each bit position) may be grouped, that is, secondarily compressed to ((m+1)/(/+1)) pieces of data. Accordingly, the ((m+1)/(/+1)) pieces of grouping data may be generated in each of the bit positions. The output signals DQ<0:z> based on the compression signals CODE<0:/> generated in the same bit position of the serial compression signals COMP_SD0<0:n> to COMP_SDm<0:n> may be simultaneously output through the output channels, that is, may be output through corresponding output channels in parallel. The output signals DQ<0:z> based on the compression signals CODE<0:/> generated in different bit positions of the serial compression signals COMP_SD0<0:n> to COMP_SDm<0:n> may be sequentially output through a corresponding output channel.

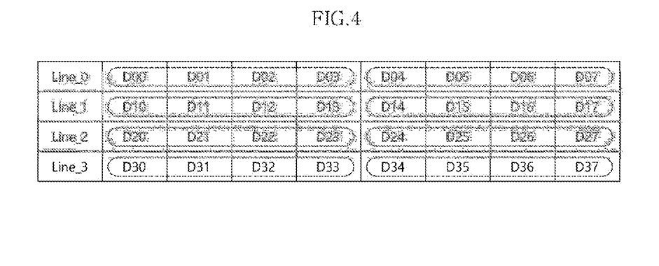

FIG. 3 is a configuration diagram illustrating a representation of an example of an encoder according to an embodiment.

Referring to FIG. 3, an encoder 220-1 may include a plurality of encoding circuits 2210-0 to 2210-m provided in the data transmission lines Line_0 to Line_m.

Each of the encoding circuits 2210-0 to 2210-m may include a grouping circuit 221-0 to 221-m and a buffer 223-0 to 223-m.

The grouping circuit 221-0 to 221-m may be configured to output grouping data COMP_mx<0:/> (x={(n+1)/(/+1)}−1) by grouping the bit signals of each of the serial compression signals COMP_SD0<0:n> to COMP_SDm<0:n> provided through a corresponding data transmission line Line_0 to Line_m in units of preset number (/+1).

The buffer 223-0 to 223-m may be configured to temporarily store the grouping data COMP_mx<0:/> provided from the grouping circuit 221-0 to 221-m, and sequentially output the grouping data COMP_mx<0:/> as the compression signal CODEm<0:/>.

Bit signals of a corresponding compression signal CODEm<0:/> output from the encoding circuit 2210-0 to 2210-m coupled to the corresponding data transmission line Line_0 to Line_m may be sequentially output in bit units. Corresponding bit signals of the compression signal CODEm<0:1> output from the encoding circuits 2210-0 to 2210-m coupled to different data transmission lines Line_0 to Line_m may be simultaneously output.

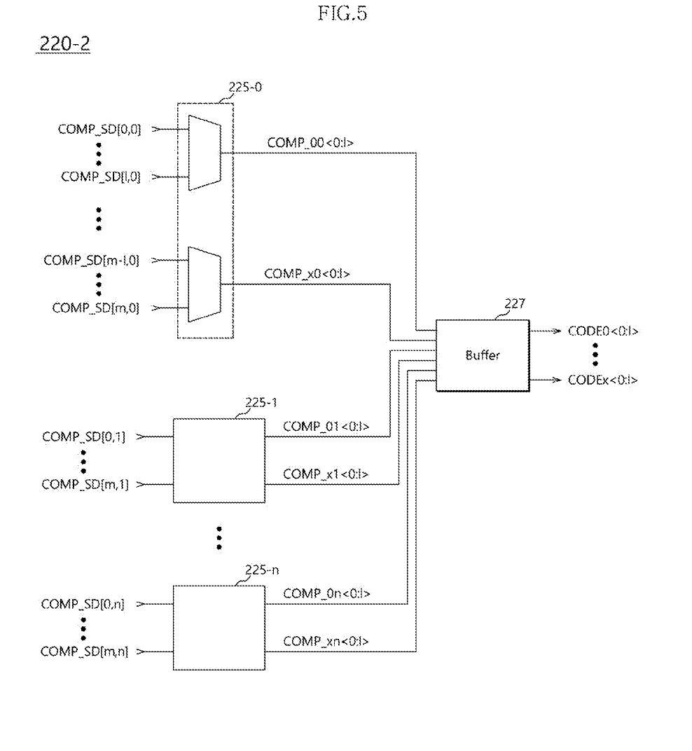

FIG. 4 is a diagram explaining a representation of an example of a grouping concept according to an embodiment.

FIG. 4 illustrates an example of data grouping for explaining the method (Case \textcircled{1}) of encoding the bit signals of each of the compression signals COMP_PD0<0:n> to COMP_PDm<0:n> in the data transmission lines Line_0 to Line_m through the second data compressor 200.

Referring to FIG. 4, data as the compression signal transmitted through each of four data transmission lines Line_0 to Line_{—3 (m=}3) may be, for example, 8 bit data (n=7). Data in each of the data transmission lines may be grouped in 4 bit units.

The 8 bit data transmitted through each data transmission line Line_0 to Line_m may be grouped in 4 bit units in each of the grouping circuits 221-0 to 221-3, and be generated as the grouping data COMP_mx<0:3> (m={0, 1, 2, 3}, x={0, 1}). The grouping data COMP_mx<0:3> may be generated as the compression signal CODEm<0:3> (m={0, 1, 2, 3}) through the buffers 223-0 to 223-3. A voltage signal corresponding to the logic level of the compression signal COMP_mx<0:3> may be generated as the output signal DQ<0:3> through the output circuit 230.

The signal and data in the encoding method (Case \textcircled{1}) may be listed as illustrated in the following Table 1.

TABLE 1

| Data | | Compression | Output |
|---|---|---|---|
| transmission line | Grouping data | signal | signal |
| Line_0 | COPM_00<0:3> | CODE0<0:3> | DQ[0] |
| | COPM_01<0:3> | | |
| Line_1 | COPM_10<0:3> | CODE1<0:3> | DQ[1] |
| | COPM_11<0:3> | | |
| Line_2 | COPM_20<0:3> | CODE2<0:3> | DQ[2] |
| | COPM_21<0:3> | | |
| Line_3 | COPM_30<0:3> | CODE3<0:3> | DQ[3] |
| | COPM_31<0:3> | | |

The buffers 223-0 to 223-3 may control the output signals DQ<0:z> based on the grouping data COMP_mx<0:3> and the compression signal CODEm<0:3> generated in the same data transmission line Line_0 to Line_3 to be sequentially output. For example, a first grouping data COMP_00<0:3> and a second grouping data COMP_01<0:3> may be generated in the first data transmission line Line_0, and may be sequentially output as the compression signal CODE0<0:3>. A voltage signal corresponding to a logic level of the first grouping data COMP_00<0:3> and a voltage signal corresponding to a logic level of the second grouping data COMP_01<0:3> may be sequentially output as the output signal DQ[0] through the same output channel.

The first grouping data COMP_m0<0:3> in the data transmission lines Line_0 to Line_3 may be simultaneously output through separate output channels. Similarly, the second grouping data COMP_m1<0:3> in the data transmission lines Line_0 to Line_3 may be simultaneously output through separate output channels.

FIG. 5 is a configuration diagram illustrating a representation of an example of an encoder according to an embodiment.

Referring to FIG. 5, an encoder 220-2 may include encoding circuits 225-0 to 225-n provided to correspond to bit positions of the serial compression signals COMP_SD0<0:n> to COMP_SDm<0:n> and a buffer 227 configured to output output signals of the encoding circuits 225-0 to 225-n through a preset method.

The encoding circuits 225-0 to 225-m may be provided to correspond to a first bit position to a (n+1)-th bit position of the serial compression signals COMP_SD0<0:n> to COMP_SDm<0:n>. The encoding circuits 225-0 to 225-m may be configured to generate the grouping data COMP_xn<0:/> (x={(m+1)/(/+1)}−1) by grouping the m pieces of data located in each of the bit positions of the serial compression signals COMP_SD0<0:n> to COMP_SDm<0:n> in (/+1) units.

The buffer 227 may be configured to output the compression signal CODE0<0:/> to CODEx<0:/> in such a manner that the grouping data generated in the same bit position may be simultaneously output through separate output channels, and the grouping data in the bit positions may be sequentially output through a corresponding output channel.

That is, the buffer 227 may be configured to simultaneously output the grouping data for bit signals of the serial compression signals in each of the bit positions, which are generated in the encoding circuits 225-0 to 225-m, and sequentially output the grouping data for the bit signals in the bit positions of the serial compression signals, which are generated in the encoding circuits 225-0 to 225-m.

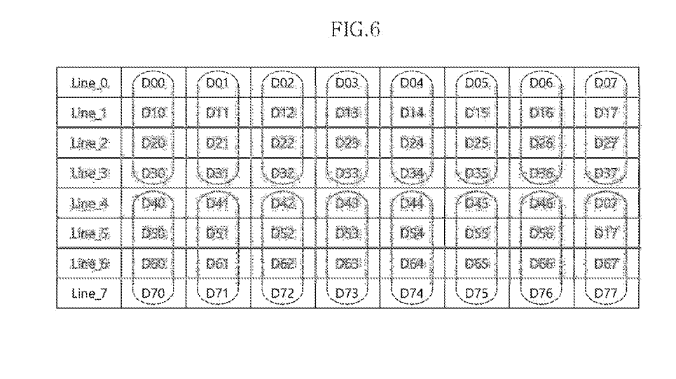

FIG. 6 is a diagram explaining a representation of an example of a grouping concept according to an embodiment.

FIG. 6 illustrates an example of data grouping for explaining the method (Case \textcircled{2}) of encoding the bit signals in the same bit position of the compression signals COMP_PD0<0:n> to COMP_PDm<0:n> in the data transmission lines Line_0 to Line-m through the second data compressor 200.

Referring FIG. 6, data as the compression signal transmitted through each of eight data transmission lines Line_0 to Line_{—7 (m=}7) may be 8 bit data (n=7). Data in each bit position of the compression signals may be grouped in 4 bit units (/=3).

The 8 bit data located in each of the bit positions <0:7> of the serial compression signals may be grouped in four bit units in each of the encoding circuits 225-0 to 225-m, and be generated as the grouping data COMP_xn<0:3> (x={0, 1}, n={0, 1, 2, 3, 4, 5, 6, 7}). The grouping data COMP_xn<0:3> may be generated as the compression signal CODEx<0:3> (x={0, 1}) in the buffer 227. A voltage signal corresponding to the logic level of the compression signal CODEx<0:3> may be generated as the output signal DQ<0:1> through the output circuit 230.

The signal and data in the encoding method (Case \textcircled{2}) may be listed as illustrated in the following Table 2.

TABLE 2

| Data | | | | | | | |
|---|---|---|---|---|---|---|---|
| transmission | Bit position | | | | | Compression | Output |
| line | 0 | 1 | . . . | 6 | 7 | signal | signal |
| Line_0 | COMP_00<0:3> | COMP_01<0:3> | . . . | COMP_06<0:3> | COMP_07<0:3> | CODE0<0:3> | DQ[0] |
| Line_1 | | | | | | | |
| Line_2 | | | | | | | |
| Line_3 | | | | | | | |
| Line_4 | COMP_10<0:3> | COMP_11<0:3> | . . . | COMP_16<0:3> | COMP_17<0:3> | CODE1<0:3> | DQ[1] |
| Line_5 | | | | | | | |
| Line_6 | | | | | | | |
| Line_7 | | | | | | | |

The buffer 227 may control the output signal DQ<0:1> based on the grouping data COMP_xn<0:3> and the compression signal CODEx<0:3>, which are generated in the same bit position <0:3>, to be simultaneously output. For example, the first grouping data COMP_00<0:3> and the second grouping data COMP_10<0:3> in the first bit position of the serial composition signals may be generated, and may be simultaneously output as the first compression signal CODE0<0:3> and the second compression signal CODE1<0:3>. The first grouping data COMP_00<0:3> (that is, the voltage signal corresponding to the logic level of the first compression signal CODE0<0:3>) and the second grouping data COMP_10<0:3> (that is, the voltage signal corresponding to the logic level of the second compression signal CODE1<0:3> may be simultaneously output as the output signals DQ[0] and DQ[1] through separate output channels.

The compression signals CODE0<0:3> and the compression signals CODE1<0:3> generated in the bit positions of the serial compression signals may be sequentially output through corresponding output channels.

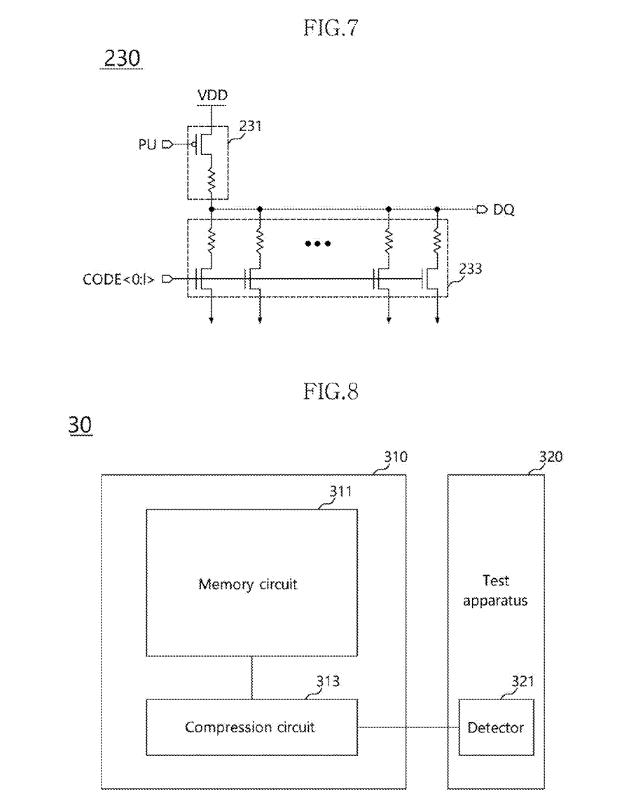

FIG. 7 is a configuration diagram illustrating a representation of an example of an output circuit according to an embodiment.

Referring to FIG. 7, the output circuit 230 may include a first driver 231 and a second driver 233.

The first driver 231 may be driven in response to a pull up signal PU.

The second driver 233 may be configured to output a voltage signal corresponding to a logic level of the compression signal CODE<0:/) to an output node DQ.

In an embodiment, the second driver 233 may include a plurality of switching elements driven according to the logic level of the compression signal CODE<0:/>.

The compression signal CODE<0:/> may be a (/+1) bit digital code, and may be represented as (/+1) different voltage signals.

In an embodiment, an amount of current may be controlled by the compression signal CODE<0:/>, and thus the voltage signal corresponding to the logic level of the compression signal CODE<0:/>may be applied to the output node DQ.

The configuration of the output circuit 230 is not limited thereto, and any configuration configured to receive a digital signal of plural bits and generate a voltage signal corresponding to the digital signal may be applied as the output circuit 230.

When the method of encoding the data in each of the data transmission lines Line_0 to Line_m in preset number units is used in the encoder 220, the output circuit 230 may be provided to each of the data transmission lines Line_0 to Line_m. That is, m output circuits 230 may be provided with respect to the data transmission lines Line_0 to Line_m.

When the method of encoding the data located in the same bit position in the data transmission lines Line_0 to Line_m is used in the encoder 220, the output circuits 230 may be provided to correspond to the grouping number (m+1)/(/+1).

The output circuit 230 in the embodiment may be configured to output the compression signal CODE<0:/> not as the logic level of 0 (zero) or 1 but as any one of 2⁽¹⁺¹⁾ voltage levels.

When the compression signals COMP_PD0<0:n> to COMP_PDm<0:n> transmitted in parallel are serialized and intactly output, the data may be represented as the logic level of 0 (zero) or 1 with respect to each bit.

However, the embodiment may reduce the number of data to be output by grouping and encoding the compression signals COMP_PD0<0:n> to COMP_PDm<0:n> by a preset number with respect to the compression signal in each data transmission line or with respect to the same bit position the compression signals in the data transmission lines. The embodiment may generate the output signal DQ<0:z> having the voltage level corresponding to the logic level of the grouped and encoded data. Accordingly, the test read data finally output, that is, the number of output signals DQ<0:z> (the burst length or the number of channels) may be reduced.

Since the output signal DQ<0:z> may include information before the grouping, the test apparatus may determine whether or not the semiconductor memory apparatus is failed according to the output signal and may also trace an address of a memory region in which the fail occurs.

The test apparatus which determines whether or not the semiconductor memory apparatus 10 is failed from the output signal DQ<0:z> acquired from the semiconductor memory apparatus 10 described with reference to FIGS. 1 to 7 may be necessary.

FIG. 8 is a configuration diagram illustrating a representation of an example of a semiconductor apparatus according to an embodiment.

Referring to FIG. 8, a semiconductor apparatus 30 may include a semiconductor memory apparatus 310 and a test apparatus 320.

The semiconductor memory apparatus 310 may include a memory circuit 311 and a compression circuit 313.

The memory circuit 311 may include a memory region including a plurality of memory cells in which data is stored, and an address decoder, a write circuit unit, a read circuit unit, and the like configured to write data to the memory region and read data from the memory region. The memory cell may be a volatile memory device such as a dynamic random access memory (DRAM) or a nonvolatile memory device such as a flash memory or a resistive memory, but the memory cell is not limited thereto.

For example, the compression circuit 313 may be configured to include the first data compressor 100 and the second data compressor 200 illustrated in FIG. 1.

Accordingly, the compression circuit 313 may generate compression signals COMP_PD0<0:n> to COMP_PDm<0:n> which are simultaneously output by compressing test data TEST_RD<0:y> provided through the memory circuit 311 in a preset compression rate, generate grouping data by grouping the compression signals COMP_PD0<0:n> to COMP_PDm<0:n> in preset bit units, and output an output signal DQ<0:z> corresponding to a logic level of the grouping data.

The test apparatus 320 may include a detector 321.

The detector 321 may be configured to determine whether the test data TEST_RD<0:y> is PASS or FAIL according to the output signal DQ<0:z> provided from the compression circuit 313, and to detect an address of the failed memory region.

The output signal DQ<0:z> provided from the compression circuit 313 may be transmitted through at least one output channel.

The detector 321 may be configured to convert a voltage level of the output signal DQ<0:z> provided through each output channel to a digital signal.

FIG. 9 is a configuration diagram illustrating a representation of an example of a detector according to an embodiment.

Referring to FIG. 9, the detector 321 may include decoders 3211-0 to 3211-z and a determiner 3213.

The decoders 3211-0 to 3211-z may be provided in the transmission channels, respectively. The decoders 3211-0 to 3211-z may be configured to output a decoding signal DEC<0:q> (that is, DECO to DECq) by comparing the output signal DQ<0:z> provided through the transmission channel with a plurality of reference voltages REF0 to REFq (q=2^{(/+1)}−1).

The determiner 3123 may determine the logic level of the output signal DQ<0:z> based on the decoding signal DEC<0:q>. The determiner 3213 may determine whether or not a memory region, which transmits the compression signals COMP_PD0<0:n> to COMP_PDm<0:n> which the corresponding output signal DQ<0:z> is generated based thereon, is failed according to a determination result. When the memory region is determined as FAIL, the determiner 3213 may control an address of the corresponding memory region to be stored and control the corresponding memory region to be repaired.

Since the decoding signals generated from the decoders 3211-0 to 3211-z may include information before the output signal DQ<0:z> is grouped, the test apparatus 320 may determine whether or not the semiconductor memory apparatus is failed according to the decoding signals, and trace the address of the memory region in which the fail occurs.

The above embodiments are illustrative and not limitative. Various alternatives and equivalents are possible. The disclosure is not limited by the embodiments described herein. Nor are the embodiments limited to any specific type of semiconductor device. Other additions, subtractions, or modifications are obvious in view of the present disclosure and are intended to fall within the scope of the appended claims.

What is claimed is:

1. A semiconductor memory apparatus comprising:
a first data compressor configured to generate at least one compression signal based on test data provided in a memory circuit; and
a second data compressor configured to generate grouping data by grouping the at least one compression signal in preset bit units and generate an output signal having a voltage level corresponding to a logic level of the grouping data.

2. The semiconductor memory apparatus of claim 1, wherein the compression signal is transmitted in plural bits through each of data transmission lines, and
the second data compressor is configured to group the compression signal in each of the data transmission lines in the preset bit units.

3. The semiconductor memory apparatus of claim 2, wherein the second data compressor is configured to sequentially output output signals corresponding to compression signals transmitted through the same data transmission line.

4. The semiconductor memory apparatus of claim 2, wherein the second data compressor is configured to simultaneously output output signals corresponding to compression signals transmitted through the data transmission lines.

5. The semiconductor memory apparatus of claim 1, wherein the compression signal is transmitted in plural bits through each of data transmission lines, and
the second data compressor is configured to group bit signals located in the same bit position among bit positions of the compression signals transmitted through the data transmission lines in the preset bit units.

6. The semiconductor memory apparatus of claim 5, wherein the second data compressor is configured to simultaneously output output signals based on pieces of grouping data generated by grouping the bit signals located in each of the bit positions of the compression signals.

7. The semiconductor memory apparatus of claim 5, wherein the second data compressor is configured to sequentially output output signals based on pieces of grouping data generated by grouping the bit signals located in the bit positions of the compression signals.

8. A semiconductor memory apparatus comprising:
a first data compressor configured to generate at least one parallel compression signal simultaneously output by receiving test data from a memory circuit;
a parallel to serial converter configured to convert the parallel compression signal to a serial compression signal;
an encoder configured to generate grouping data by grouping the serial compression signal in preset bit units; and
an output circuit configured to generate an output signal having a voltage level corresponding to a logic level of the grouping data.

9. The semiconductor memory apparatus of claim 8, wherein the serial compression signal is transmitted in plural bits through each of data transmission lines, and
the encoder includes:
a grouping circuit configured to generate at least one piece of grouping data by grouping bit signals of the serial compression signal transmitted through each of the data transmission lines in the preset bit units; and
a buffer configured to sequentially output the at least one piece of grouping data.

10. The semiconductor memory apparatus of claim 9, wherein the grouping circuit and the buffer are provided for each of the data transmission lines, and output signals of the buffers provided for the data transmission lines are simultaneously output.

11. The semiconductor memory apparatus of claim 8, wherein the serial compression signal is transmitted in plural bits through each of data transmission lines, and
the encoder includes:
an encoding circuit configured to generate at least one piece grouping data in each of bit positions of serial compression signals by grouping bit signals located in the same bit position among the bit positions of the serial compression signals transmitted in the plural bits through the data transmission lines in the preset bit units; and
a buffer configured to output the at least one piece of grouping data.

12. The semiconductor memory apparatus of claim 11, wherein the buffer is configured to simultaneously output pieces of grouping data generated in the same bit position among the bit positions of the serial compression signals.

13. The semiconductor memory apparatus of claim 11, wherein the buffer is configured to sequentially output pieces of grouping data generated in the bit positions.

14. A semiconductor apparatus comprising:
a semiconductor memory apparatus configured to generate grouping data by grouping at least one compression signal generated in response to test data provided from a memory circuit in preset bit units and generate an output signal having a voltage level corresponding to a logic level of the grouping data; and
a test apparatus configured to determine whether the semiconductor memory apparatus has a memory region which has failed in response to the output signal.

15. The semiconductor apparatus of claim 14, wherein the test apparatus is configured to convert the output signal to a digital signal.

16. The semiconductor apparatus of claim 14, wherein the test apparatus is configured to generate a decoding signal by comparing the output signal with a plurality of reference voltages.

17. The semiconductor apparatus of claim 14, wherein the compression signal is transmitted in plural bits through each of data transmission lines, and
the semiconductor memory apparatus is configured to group the compression signal in each of the data transmission lines in the preset bit units.

18. The semiconductor apparatus of claim 17, wherein the semiconductor memory apparatus is configured to sequentially output output signals corresponding to compression signals transmitted through the same data transmission line.

19. The semiconductor apparatus of claim 17, wherein the semiconductor memory apparatus is configured to simultaneously output output signals corresponding to compression signals transmitted through the data transmission lines.

20. The semiconductor apparatus of claim 14, wherein the compression signal is transmitted in plural bits through each of data transmission lines, and
the semiconductor memory apparatus is configured to group bit signals located in the same bit position among bit positions of the compression signals transmitted through the data transmission lines in the preset bit units.

21. The semiconductor apparatus of claim 20, wherein the semiconductor memory apparatus is configured to simultaneously output output signals based on pieces of grouping data generated by grouping the bit signals located in the same bit position among the bit positions of the compression signals.

22. The semiconductor apparatus of claim 20, wherein the semiconductor memory apparatus is configured to sequentially output output signals based on pieces of grouping data generated by grouping bit signals located in the bit positions of the compression signals.

23. The semiconductor apparatus of claim 14, wherein the semiconductor memory apparatus includes:
a first data compressor configured to generate at least one parallel compression signal simultaneously output by receiving the test data from the memory circuit;
a parallel to serial converter configured to convert the parallel compression signal to a serial compression signal;
an encoder configured to generate the grouping data by grouping the serial compression signal in the preset bit units; and
an output circuit configured to generate an output signal having a voltage level corresponding to a logic level of the grouping data.

24. A compression circuit comprising:
a first data compressor configured to generate at least one compression signal based on test data; and
a second data compressor configured to generate grouping data by grouping the at least one compression signal in preset bit units and generate an output signal having a voltage level corresponding to a logic level of the grouping data.

25. The compression circuit of claim 24, wherein the compression signal is transmitted in plural bits through each of data transmission lines, and
the second data compressor is configured to group the compression signal in each of the data transmission lines in the preset bit units.

26. The compression circuit of claim 25, wherein the second data compressor is configured to sequentially output output signals corresponding to compression signals transmitted through the same data transmission line.

27. The compression circuit of claim 25, wherein the second data compressor is configured to simultaneously output output signals corresponding to compression signals transmitted through the data transmission lines.

28. The compression circuit of claim 24, wherein the compression signal is transmitted in plural bits through each of data transmission lines, and
the second data compressor is configured to group bit signals located in the same bit position among bit positions of the compression signals transmitted through the data transmission lines in the preset bit units.

29. The compression circuit of claim 28, wherein the second data compressor is configured to simultaneously output output signals based on pieces of grouping data generated by grouping the bit signals located in each of the bit positions of the compression signals.

30. The compression circuit of claim 28, wherein the second data compressor is configured to sequentially output output signals based on pieces of grouping data generated by grouping the bit signals located in the bit positions of the compression signals.

31. The compression circuit of claim 24, wherein the test data is provided from a memory circuit.

32. A compression circuit comprising:
a first data compressor configured to generate at least one parallel compression signal simultaneously output by receiving test data;
a parallel to serial converter configured to convert the parallel compression signal to a serial compression signal;
an encoder configured to generate grouping data by grouping the serial compression signal in preset bit units; and
an output circuit configured to generate an output signal having a voltage level corresponding to a logic level of the grouping data.

33. The compression circuit of claim 32, wherein the test data is provided from a memory circuit.

34. The compression circuit of claim 32, wherein the serial compression signal is transmitted in plural bits through each of data transmission lines, and
the encoder includes:
a grouping circuit configured to generate at least one piece of grouping data by grouping bit signals of the serial compression signal transmitted through each of the data transmission lines in the preset bit units; and
a buffer configured to sequentially output the at least one piece of grouping data.

35. The compression circuit of claim 32, wherein the serial compression signal is transmitted in plural bits through each of data transmission lines, and
the encoder includes:
an encoding circuit configured to generate at least one piece grouping data in each of bit positions of serial compression signals by grouping bit signals located in the same bit position among the bit positions of the serial compression signals transmitted in the plural bits through the data transmission lines in the preset bit units; and
a buffer configured to output the at least one piece of grouping data.

36. A test apparatus comprising:
a detector configured to receive an output signal having a voltage level corresponding to a logic level of grouping data to determine whether a memory region has failed,
wherein the grouping data is generated by grouping at least one compression signal generated in response to test data provided in preset bit units.

37. The test apparatus of claim 36, wherein the test data is provided from a memory circuit.

38. The test apparatus of claim 36, further comprising:
a decoder configured to convert the output to a digital signal.

39. The test apparatus of claim 36, further comprising:
a decoder configured to generate a decoding signal by comparing the output signal with a plurality of reference voltages.

40. The test apparatus of claim 36, wherein the compression signal is transmitted in plural bits through each of data transmission lines, and
the semiconductor memory apparatus is configured to group the compression signal in each of the data transmission lines in the preset bit units.

41. The test apparatus of claim 36, wherein the compression signal is transmitted in plural bits through each of data transmission lines, and
wherein group bit signals are located in the same bit position among bit positions of the compression signals transmitted through the data transmission lines in the preset bit units.
